(19) United States
(12) Patent Application Publication
(10) Pub. No.: US 2025/0342899 A1
(43) Pub. Date: Nov. 6, 2025

(54) SYSTEM AND METHOD FOR SWAPPING FAULTY MEMORY ADDRESSES IN A MICROCONTROLLER

(71) Applicant: Microchip Technology Incorporated, Chandler, AZ (US)

(72) Inventor: Henrik Nyholm, Trondheim (NO)

(73) Assignee: Microchip Technology Incorporated, Chandler, AZ (US)

(21) Appl. No.: 19/198,492

(22) Filed: May 5, 2025

Related U.S. Application Data
(60) Provisional application No. 63/642,415, filed on May 3, 2024.

(51) Int. Cl. G11C 29/00; G11C 7/10; G11C 29/52

(52) U.S. Cl. CPC G11C 29/76; G11C 7/1012; G11C 29/52

(57) ABSTRACT

Disclosed herein are system, method, and computer-readable medium aspects for swapping faulty memory addresses in a microcontroller. An example aspect includes a fault detection circuitry, a blacklist register, a comparator, a control circuitry, a first memory, and a second memory. The fault detection circuitry detects a faulty memory address in the first memory. The blacklist register stores the faulty memory address detected by the fault detection circuitry. The comparator compares a target memory address for a requested operation with the faulty memory address stored in the blacklist register. In response to a match between the target memory address and the faulty memory address stored in the blacklist register, the control circuitry then directs the requested operation to a functional memory address in the second memory.

### CROSS-REFERENCE TO RELATED APPLICATION

The present application claims priority from U.S. Provisional Patent Application No. 63/642,415 filed on May 3, 2024, the disclosure of which is incorporated herein by reference in its entirety.

### TECHNICAL FIELD

The present disclosure relates generally to microcontrollers, and more specifically to a system, method, and computer-readable medium for swapping faulty memory addresses in a microcontroller.

### SUMMARY

According to an aspect of one or more examples, there is provided a system. The system may include a first memory, a second memory, a fault detection circuitry to detect a faulty memory address in the first memory, a blacklist register to store the faulty memory address detected by the fault detection circuitry, a comparator to compare a target memory address for a requested operation with the faulty memory addresses stored in the blacklist register, and a control circuity to, in response to a match between the target memory address and the faulty memory address stored in the blacklist register, direct the requested operation to a functional memory address in the second memory, thereby enabling continued operation of a microcontroller.

The system may include a memory controller to access and manage the first memory and the second memory. The fault detection circuitry may use one or more software diagnostics to detect the faulty memory address in the first memory. The fault detection circuitry may be an error correcting code (ECC) circuitry. The blacklist register may be volatile and the one or more faulty memory addresses may be cleared in response to a reset of the microcontroller. The blacklist register may be non-volatile and the one or more faulty memory addresses may be persistently stored. The first memory may include one of a volatile memory and a non-volatile memory. The second memory may include a pre-defined set of memory addresses reserved for when the requested operation is directed to the second memory. The control circuitry may activate a bus stall signal in response to the match between the target memory address and the one or more faulty memory addresses.

According to an aspect of one or more examples, there is provided a method for swapping faulty memory addresses in a microcontroller. The method may include detecting a faulty memory address in a first memory, storing the faulty memory address in a register, comparing a target memory address for a requested operation with the faulty memory address stored in the register, and, in response to a match between the target memory address and the faulty memory address in the register, directing the requested operation to a functional memory address in a second memory, thereby enabling continued operation of a microcontroller.

The detecting may be performed by a fault detection circuitry which may use one or more software diagnostics to detect the faulty memory address of the first memory. The fault detection circuitry may alternatively be an error correcting code (ECC) circuitry. The storing may be performed by a blacklist register which may be volatile and the one or more faulty memory addresses may be cleared in response to a reset of the microcontroller. The blacklist register may alternatively be non-volatile and the one or more faulty memory addresses may be persistently stored. The first memory may include one of a volatile memory and a non-volatile memory. The second memory may include a pre-defined set of memory addresses reserved for when the requested operation is directed to the second memory. The method may include activating a bus stall signal in response to the match between the target memory address and the one or more faulty memory addresses.

According to an aspect of one or more examples, there is provided a computer-readable medium for swapping faulty memory addresses in a microcontroller. The computer-readable medium has instructions stored thereon that, when executed by at least one computing device, cause the at least one computing device to perform operations. These operations may include receiving a first memory address associated with an operation, retrieving a list of faulty memory addresses, comparing the first memory address to the list of faulty memory addresses, and, in response to the first memory address matching to the list of faulty memory addresses, directing the operation to a second memory address.

The operations may include activating a bus stall signal in response to the first memory address matching to the list of faulty memory addresses. The operations may also include outputting a signal to indicate a matching status and to cause a multiplexer to output data received from one of the first memory and the second memory.

Further features and advantages, as well as the structure and operation of various examples, are described in detail below with reference to the accompanying drawings. It is noted that the specific examples described herein are not intended to be limiting. Such examples are presented herein for illustrative purposes only. Additional examples will be apparent to persons skilled in the relevant art(s) based on the teachings contained herein.

### BRIEF DESCRIPTION OF DRAWINGS

The accompanying drawings, which are incorporated herein and form a part of the specification, illustrate examples of the present disclosure and, together with the detailed description, further serve to explain the principles of the disclosure and to enable a person skilled in the pertinent art to make and use the disclosure.

FIG. 1 shows a block diagram illustrating a system for swapping faulty memory addresses in a microcontroller according to one or more examples.

FIG. 2 shows a block diagram illustrating a memory management circuitry in a system for swapping faulty memory addresses in a microcontroller according to one or more examples.

FIG. 3 shows a block diagram illustrating an ECC-based memory management circuitry in a system for swapping faulty memory addresses in a microcontroller according to one or more examples.

FIG. 4 shows a block diagram illustrating a method for swapping faulty memory addresses in a microcontroller according to one or more examples.

In the drawings, like reference numbers generally indicate identical or similar elements. Additionally, generally, the left-most digit(s) of a reference number identifies the drawing in which the reference number first appears. In addition, unless mention is made below to the contrary, it is noted that the drawings may not be to scale.

### DETAILED DESCRIPTION OF VARIOUS EXAMPLES

Reference will now be made in detail to the following various examples for swapping faulty memory addresses in a microcontroller, which are illustrated in the accompanying drawings, wherein like reference numerals refer to like elements throughout. The following examples may be embodied in various forms without being limited to the examples set forth herein.

Microcontrollers are used in electronic devices to perform tasks in safety-focused applications like automotive, industrial controls, medical devices, aerospace systems and defense systems. However, the microcontrollers may develop permanent memory faults over time, leading to potential malfunctions and system failures. The microcontrollers often use software or hardware-based error correcting codes (ECCs) to manage the memory faults. The management of memory faults using software may be challenging due to abstraction layers that hide memory addresses from programs. Hardware-based ECCs may detect the memory faults, but are incapable of correcting these memory faults. Therefore, there is a need for a system and method for swapping faulty memory addresses in the microcontroller.

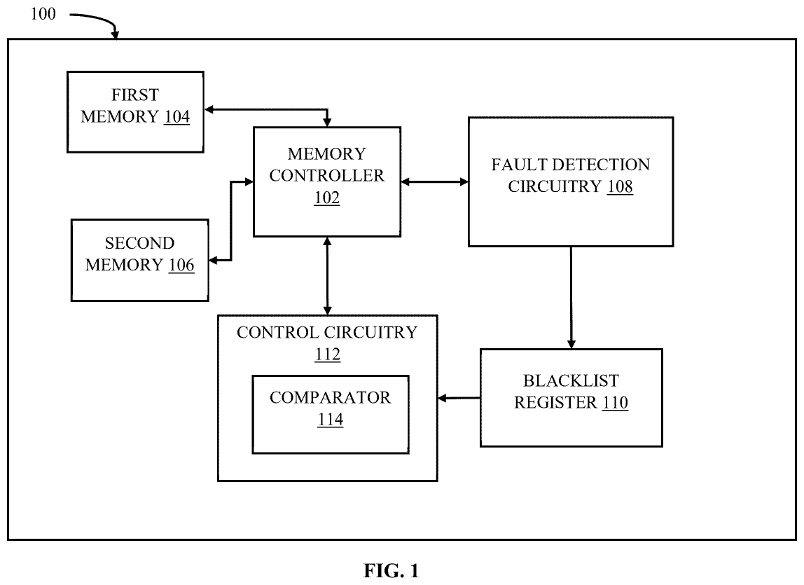

FIG. 1 shows a block diagram illustrating a system 100 for swapping faulty memory addresses in a microcontroller according to one or more examples. The system 100 may include a memory controller 102, a first memory 104, a second memory 106, a fault detection circuitry 108, a blacklist register 110 and a control circuitry 112. The control circuitry 112 may include a comparator 114. Alternatively, control circuitry 112 and comparator 114 may be separate components.

The memory controller 102 may access the first memory 104 and the second memory 106. The first memory 104 and the second memory 106 may be operably coupled to the memory controller 102. The memory controller may also be operably coupled to the fault detection circuitry 108, the control circuitry 112, and the comparator 114. The memory controller 102 may receive memory access requests from the microcontroller. The memory access requests may include a pre-defined operation and a target memory address on an address bus. The pre-defined operation may be one of a read operation and a write operation. The memory controller 102 may direct the first memory 104 or the second memory 106 to carry out the memory access requests based on the target memory address.

The memory controller 102 may manage data transfer between the microcontroller, the first memory 104 and the second memory 106 based on the memory access requests. The memory controller 102 may use a write data bus for the write operation to transfer the data from the microcontroller to the selected first memory 104 or second memory 106. The memory controller 102 may retrieve the data from the first memory 104 or the second memory 106 for the read operation and transmit the data to the microcontroller on a read data bus.

The first memory 104 may include one of a volatile memory and a non-volatile memory, or a combination of both. In one or more examples, the first memory 104 may include a random-access memory (RAM), a dynamic random-access memory (DRAM), a read-only memory (ROM), a static random-access memory (SRAM), a solid-state disk (SSD), a flash memory, a phase change memory (PCM), or other types of data storage. The first memory 104 may operate as a main memory for the microcontroller. The first memory 104 may develop a fault in one or more memory addresses over time. The fault may be a permanent fault or a transient fault. A permanent fault may be a fault caused by permanent damage to a memory cell or data. A transient fault may be a temporary data corruption caused by external factors, such as electrical noise in or around the microcontroller, or other similar factors without limitation. During a normal operation, the microcontroller may send memory access requests specifying a target address in the first memory 104, and the memory controller 102 may direct the first memory 104 to carry out the memory access requests to transfer the data accordingly.

The second memory 106 may include one of a volatile memory and a non-volatile memory, or a combination of both. In one or more examples, the second memory 106 may include a random-access memory (RAM), a dynamic random-access memory (DRAM), a read-only memory (ROM), a static random-access memory (SRAM), a solid-state disk (SSD), a flash memory, a phase change memory (PCM), or other types of data storage. The second memory 106 may operate as a backup or reserve memory for the microcontroller. The second memory 106 may develop fault in one or more memory addresses over time. The fault may be a permanent fault or a transient fault. A permanent fault may be a fault caused by permanent damage to a memory cell or data. A transient fault may be a temporary data corruption caused by external factors, such as electrical noise in or around the microcontroller, or other similar factors without limitation. The second memory 106 may include a pre-defined set of memory addresses reserved for swapping when the first memory 104 develops a fault in one or more memory addresses. The pre-defined set of memory addresses may be defined by address type, address mode, a mapping to different memory addresses, a mapping to a system component, a manually input mapping, an availability status, or another categorization, without limitation. During a fault detection, the memory controller 102 may redirect the memory access requests from the target address in the first memory 104 to one of the pre-defined set of memory addresses in the second memory 106.

The fault detection circuitry 108 may detect the fault in a memory address of the first memory 104. The fault detection circuitry 108 may be operatively coupled to memory controller 102 and blacklist register 110. The fault detection circuitry 108 may use one or more software diagnostics to detect the fault in the memory address of the first memory 104. The software diagnostic may include at least one of a March test, a cyclic redundancy check (CRC), a built-in self-test (BIST) and other types of software diagnostics. Alternatively, the fault detection circuitry 108 may be an error correcting code (ECC) circuitry. In one or more examples, the ECC circuitry may be a Single Error Correcting and Double Error Detecting Error Correcting Code (SECDED ECC) circuitry. For example, the ECC circuitry may detect single-bit errors in the data of the first memory 104. During the read operation, the ECC circuitry may analyze the data and perform an error check on pre-defined codes embedded within the data. If a single-bit error is detected, the ECC circuitry may provide the faulty memory address of the first memory 104 to the blacklist register 110.

The blacklist register 110 may be operatively coupled with the fault detection circuitry 108 to receive a signal about a new fault in a specific memory address of the first memory 104. The signal may trigger addition of the faulty memory address to the blacklist register 110. The blacklist register 110 may store one or more faulty memory addresses detected by the fault detection circuitry 108. The blacklist register 110 may be volatile, and the one or more faulty memory addresses may be cleared in response to a reset of the microcontroller. Alternatively, the blacklist register 110 may be non-volatile, and the one or more faulty memory addresses may be persistently stored. In one or more examples, the one or more faulty memory addresses may be manually input to the blacklist register 110. Alternatively, the one or more faulty memory addresses may be automatically stored in the blacklist register 110 when the ECC circuitry detects the fault. The blacklist register 110 may be operatively coupled with the control circuitry 112 and the comparator 114.

The control circuitry 112 may compare a target memory address associated with a requested operation with the one or more faulty memory addresses stored in the blacklist register 110 using the comparator 114. The target memory address may be the location in the first memory 104 whereby memory controller 102 may direct the first memory 104 to carry out the requested operation during normal operations. If the comparator 114 detects a match between the target memory address and one of the one or more faulty memory addresses, the control circuitry 112 may redirect the requested operation from the target memory address in the first memory 104 to a corresponding functional memory address from the pre-defined set of memory addresses in the second memory 106, thereby enabling continued operation of the microcontroller. In one or more examples, if the comparator 114 detects the match between the requested target address and one of the one or more faulty memory addresses, the control circuitry 112 may activate a bus stall signal. The bus stall signal may serve to delay execution of the requested operation within the microcontroller. The signal may delay execution of the requested operation permanently, for a pre-determined amount of time, until a condition is met, or until a manual input is received. The control circuitry 112 may be operatively coupled to the memory controller 102, the blacklist register 110, and the comparator 114.

The system 100 may increase durability of the first memory 104 and provide fail-safe operation to the microcontroller, which may increase safety in applications such as automotive, industrial controls, medical devices, aerospace systems, defense systems, and home appliances. The system 100 may be adapted to alter the size of the blacklist register and an address comparison logic of the control circuitry 112 according to a set of factors associated with the microcontroller. The set of factors may include an available chip area, a frequency of the microcontroller and the like. By using the system 100, software executed on a processor in a microcontroller has reduced complexity for error correction, so that software overhead and load on the microcontroller may be reduced.

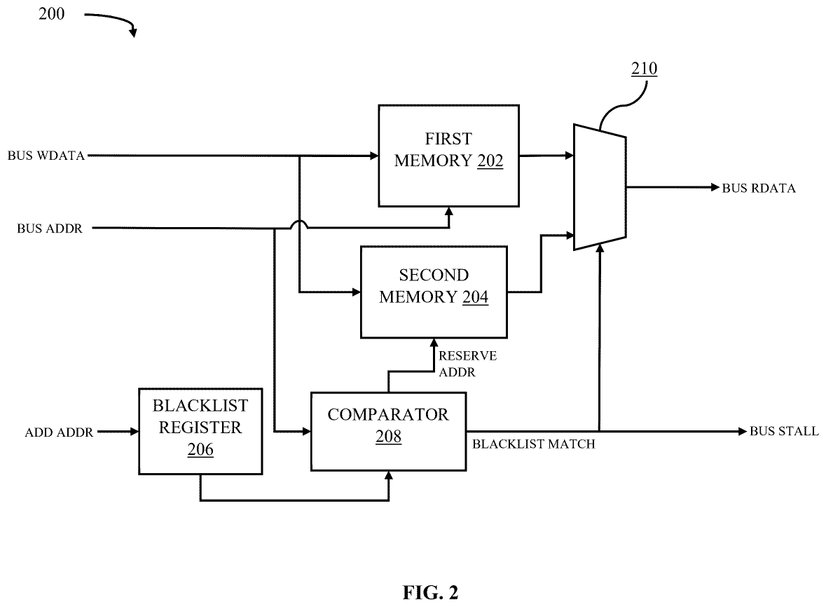

FIG. 2 shows a block diagram illustrating a memory management circuitry 200 in a system 100 for swapping faulty memory addresses in a microcontroller according to one or more examples. The memory management circuitry 200 may include a first memory 202, a second memory 204, a write data bus (BUS WDATA), an address bus (BUS ADDR), a read data bus (BUS RDATA), a blacklist register 206, a comparator 208 and a multiplexer 210.

The first memory 202 may include one of a volatile memory and a non-volatile memory, or a combination of both. In one or more examples, the first memory 202 may include a random-access memory (RAM), a dynamic random-access memory (DRAM), a read-only memory (ROM), a static random-access memory (SRAM), a solid-state disk (SSD), a flash memory, a phase change memory (PCM), or other types of data storage. The first memory 202 may operate as a main memory for the microcontroller. The first memory 202 may be operatively coupled to the BUS WDATA and the BUS ADDR.

The first memory 202 may develop a fault in one or more memory addresses over time. The fault may be a permanent fault or a transient fault. A permanent fault may be a fault caused by permanent damage to a memory cell or data. A transient fault may be a temporary data corruption caused by external factors, such as electrical noise in or around the microcontroller, or other similar factors without limitation. During a normal operation, the microcontroller may send memory access requests, BUS WDATA, specifying a target address, BUS ADDR, in the first memory 202, directing the first memory 202 to carry out the memory access requests to handle the data accordingly.

The second memory 204 may include one of a volatile memory and a non-volatile memory, or a combination of both. In one or more examples, the second memory 204 may include a random-access memory (RAM), a dynamic random-access memory (DRAM), a read-only memory (ROM), a static random-access memory (SRAM), a solid-state disk (SSD), a flash memory, a phase change memory (PCM), or other types of data storage. The second memory 204 may operate as a backup or reserve memory for the microcontroller. The second memory 204 may develop fault in one or more memory addresses over time. The fault may be a permanent fault or a transient fault. A permanent fault may be a fault caused by permanent damage to a memory cell or data. A transient fault may be a temporary data corruption caused by external factors, such as electrical noise in or around the microcontroller, or other similar factors without limitation. The second memory 204 may be operatively coupled to the BUS WDATA.

The BUS ADDR may be understood as a target memory address associated with a requested operation, BUS WDATA. The BUS WDATA may carry data from the microcontroller to a selected memory of the first memory 202 and second memory 204 during a write operation. The BUS ADDR may transmit an information related to a memory address from the microcontroller to the memory management circuitry 200. The information may correspond to a location or address in the first memory 202 that the microcontroller may access for a read operation or a write operation. The BUS RDATA may transfer the data retrieved from the first memory 202 or second memory 204 to the microcontroller during the read operation.

The blacklist register 206 may store one or more faulty memory addresses of the first memory 202. In one or more examples, the one or more faulty memory addresses may be manually added via an ADD ADDR signal in the blacklist register 206. The one or more faulty memory address may be automatically added via an ADD ADDR signal from another error detection software or hardware. The blacklist register 206 may be operatively coupled to the comparator 208. The comparator 208 may compare a target memory address on the BUS ADDR with the one or more faulty memory addresses stored in the blacklist register 206. The comparator 208 may be operatively coupled to the second memory 204 to access a reserve address (RESERVE ADDR) from a pre-defined set of memory addresses of the second memory 204. The pre-defined set of memory addresses may be defined by address type, address mode, a mapping to different memory addresses, a mapping to a system component, a manually input mapping, an availability status, or another categorization, without limitation. If the comparator 208 detects a match between the target memory address and one of the one or more faulty memory addresses, the requested operation originally to take place at the target memory address in the first memory 202 may be redirected to a corresponding functional memory address from the pre-defined set of memory addresses in the second memory 204, thereby enabling continued operation of the microcontroller. More specifically, according to various examples, the comparator 208 may output the RESERVE ADDR signal in response to detecting a match between the target memory address and one of the one or more faulty memory addresses, to cause the second memory 204 to write data from the BUS WDATA to a memory address of the second memory 204 (for a write operation), or cause the second memory 204 to output data stored at a memory address of the second memory 204 to the multiplexer 210 (for a read operation).

In one or more examples, if the comparator 208 detects the match between the target memory address and one of the one or more faulty memory addresses, a bus stall signal may be output. The bus stall signal may serve to delay execution of the requested operation within the microcontroller. The signal may delay execution of the requested operation permanently, for a pre-determined amount of time, until a condition is met, or until a manual input is received. The first memory 202, the second memory 204, and the comparator 208 may be operatively coupled to the multiplexer 210. The comparator 208 may output a BLACKLIST MATCH signal to the multiplexer 210 to indicate whether the comparator 208 has detected a match between the target memory address and one of the one or more faulty memory addresses. If the comparator 208 has detected a match between the target memory address and one of the one or more faulty memory addresses, the BLACKLIST MATCH signal may cause the multiplexer 210 to output the data received from the second memory 204. If the comparator 208 has not detected a match between the target memory address and one of the one or more faulty memory addresses, the BLACKLIST MATCH signal may cause the multiplexer 210 to output the data received from the first memory 202. Although the comparator 208 of FIG. 2 is shown as a separate component from the blacklist register 206, according to various examples, the comparator 208 may be implemented within the blacklist register 206.

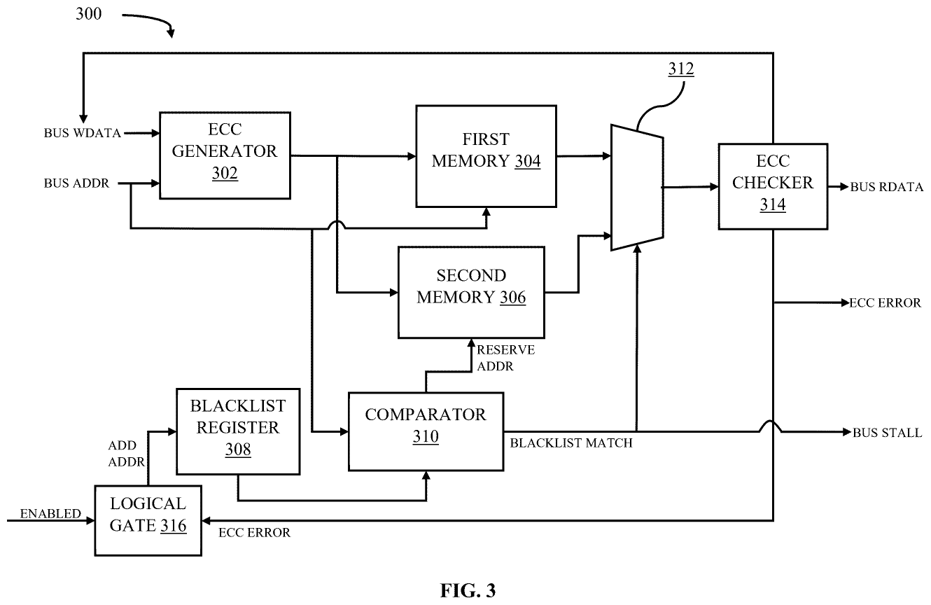

FIG. 3 shows a block diagram illustrating an ECC-based memory management circuitry 300 in a system 100 for swapping faulty memory addresses in a microcontroller according to one or more examples. The ECC-based memory management circuitry 300 may include an ECC generator 302, a first memory 304, a second memory 306, a write data bus (BUS WDATA), an address bus (BUS ADDR), a read data bus (BUS RDATA), a blacklist register 308, a comparator 310, a multiplexer 312, an ECC check 314 and a logical gate 316.

The ECC generator 302 may generate ECC codes based on data received for a write operation to the first memory 304 through the BUS WDATA. The ECC codes may be embedded in the data and stored in the first memory 304. During a read operation, the ECC codes may be used for error detection. The ECC checker 314 may perform error checking on the retrieved data from the first memory 304 using corresponding ECC codes. The ECC checker 314 may determine if any error occurred while storing or retrieving the data. If the ECC check 314 detects an error, an ECC error signal may be transmitted to the logical gate 316. In one or more examples, the logical gate 316 may be an AND gate. The ECC error signal may include one or more faulty memory addresses of the first memory 304, such as, for example, the memory address at which the erroneous data is stored.

The logical gate 316 may use the ECC error signal to store the one or more faulty memory addresses of the first memory 304 in the blacklist register 308. In one or more examples, the one or more faulty memory addresses may be automatically added via an ADD ADDR signal in the blacklist register 308 through the logical gate 316. The one or more faulty memory address may be automatically added via an ADD ADDR signal from another error detection software or hardware. The blacklist register 308 may be operatively coupled to the comparator 310. The comparator 310 may compare a target memory address on the BUS ADDR with the one or more faulty memory addresses stored in the blacklist register 308. The comparator 310 may be operatively coupled to the second memory 306 and may output a signal RESERVE ADDR to access a reserve address from a pre-defined set of memory addresses of the second memory 306. The pre-defined memory addresses may be mapped to locations in first memory 304. The pre-defined memory addresses may be mapped to items in blacklist register 308. The pre-defined memory addresses and their mappings may be manually provided or may be automatically configured. If the comparator 310 detects a match between the target memory address and one of the one or more faulty memory addresses, the target memory address may be swapped with a corresponding functional memory address from the pre-defined set of memory addresses in the second memory 306, thereby enabling continued operation of the microcontroller. More specifically, according to various examples, the comparator 310 may output the RESERVE ADDR signal in response to detecting a match between the target memory address and one of the one or more faulty memory addresses, to cause the second memory 306 to write data from the BUS WDATA to a memory address of the second memory 306 (for a write operation), or cause the second memory 306 to output data stored at a memory address of the second memory 306 to the multiplexer 312 (for a read operation).

In one or more examples, if the comparator 310 detects the match between the target memory address and one of the one or more faulty memory addresses, a bus stall signal may be output. The bus stall signal may serve to delay execution of the requested operation within the microcontroller. The signal may delay execution of the requested operation permanently, for a pre-determined amount of time, until a condition is met, or until a manual input is received. The first memory 304, the second memory 306, and the comparator 310 may be operatively coupled to the multiplexer 312. The comparator 310 may output a BLACKLIST MATCH signal to the multiplexer 312 to indicate whether the comparator 310 has detected a match between the target memory address and one of the one or more faulty memory addresses. If the comparator 310 has detected a match between the target memory address and one of the one or more faulty memory addresses, the BLACKLIST MATCH signal may cause the multiplexer 312 to output the data received from the second memory 306. If the comparator 310 has not detected a match between the target memory address and one of the one or more faulty memory addresses, the BLACKLIST MATCH signal may cause the multiplexer 312 to output the data received from the first memory 304. Although the comparator 301 of FIG. 3 is shown as a separate component from the blacklist register 308, according to various examples, the comparator 310 may implemented within the blacklist register 308.

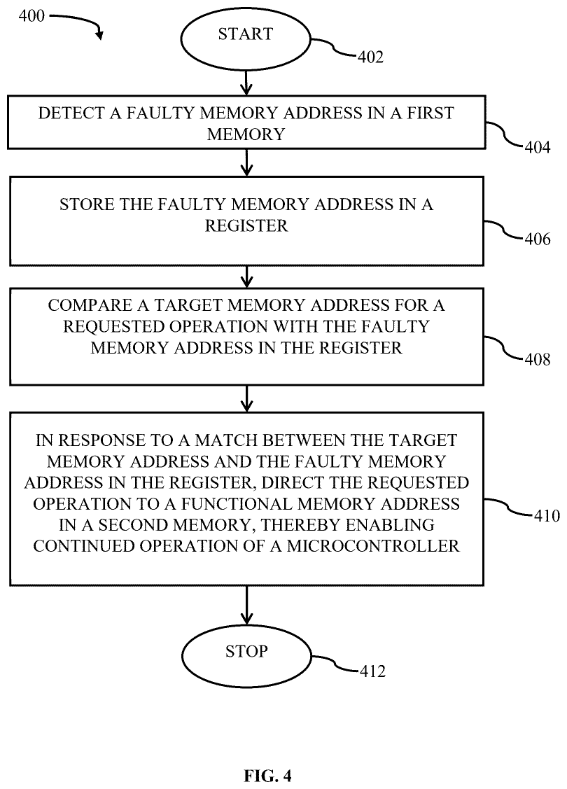

FIG. 4 shows a flowchart 400 illustrating a method for swapping faulty memory addresses in a microcontroller according to one or more examples. It may be noted that in order to explain the method operations of the flowchart 400, references will be made to the elements explained in FIG. 1.

The flowchart 400 starts at operation 402. At operation 404, the method may include detecting a faulty memory address in the first memory 104 using the fault detection circuitry 108. The first memory 104 may include one of a volatile memory and a non-volatile memory, or a combination of both. In one or more examples, the first memory 104 may include a random-access memory (RAM), a dynamic random-access memory (DRAM), a read-only memory (ROM), a static random-access memory (SRAM), a solid-state disk (SSD), a flash memory, a phase change memory (PCM), or other types of data storage. The first memory 104 may operate as a main memory for the microcontroller. The first memory 104 may develop a fault in one or more memory addresses over time. The fault may be a permanent fault or a transient fault. A permanent fault may be a fault caused by permanent damage to a memory cell or data. A transient fault may be a temporary data corruption caused by external factors, such as electrical noise in or around the microcontroller, or other similar factors without limitation.

The fault detection circuitry 108 may detect the fault in a memory address of the first memory 104. The fault detection circuitry 108 may use one or more software diagnostics to detect the fault in the memory address of the first memory 104. The software diagnostic may include at least one of a March test, a cyclic redundancy check (CRC), a built-in self-test (BIST) and other types of software diagnostics. Alternatively, the fault detection circuitry 108 may be an error correcting code (ECC) circuitry. In one or more examples, the ECC circuitry may be a Single Error Correcting and Double Error Detecting Error Correcting Code (SECDED ECC) circuitry. For example, the ECC circuitry may detect single-bit errors in the data of the first memory 104. During the read operation, the ECC circuitry may analyze the data and perform an error check on pre-defined codes embedded within the data.

At operation 406, the method may include storing the faulty memory address detected by the faulty detection circuitry 108 in the blacklist register 110. The blacklist register 110 may be operatively coupled with the fault detection circuitry 108 to receive a signal about a new fault in a specific memory address of the first memory 104. The signal may trigger addition of the faulty memory address to the blacklist register 110. The blacklist register 110 may store one or more faulty memory addresses detected by the fault detection circuitry 108. The blacklist register 110 may be volatile, and the one or more faulty memory addresses may be cleared in response to a reset of the microcontroller. Alternatively, the blacklist register 110 may be non-volatile, and the one or more faulty memory addresses may be persistently stored. In one or more examples, the one or more faulty memory addresses may be manually input to the blacklist register 110. Alternatively, the one or more faulty memory addresses may be automatically stored in the blacklist register 110 when the ECC circuitry detects the fault.

At operation 408, the method may include comparing a target memory address for a requested operation with the faulty memory address stored in the blacklist register 110 using a comparator 114.

At operation 410, the method may include re-directing the requested operation that was originally to occur using the target memory address to a corresponding functional memory address in a second memory 106, in response to a match between the target memory address and the faulty memory address, thereby enabling continued operation of the microcontroller. The second memory 106 may include one of a volatile memory and a non-volatile memory, or a combination of both. In one or more examples, the second memory 106 may include a random-access memory (RAM), a dynamic random-access memory (DRAM), a read-only memory (ROM), a static random-access memory (SRAM), a solid-state disk (SSD), a flash memory, a phase change memory (PCM), or other types of data storage. The second memory 106 may operate as a backup or reserve memory for the microcontroller. The second memory 106 may include a pre-defined set of memory addresses reserved for swapping when the first memory 104 develops a fault in one or more memory addresses. The pre-defined set of memory addresses may be defined by address type, address mode, a mapping to different memory addresses, a mapping to a system component, a manually input mapping, an availability status, or another categorization, without limitation.

The flowchart 400 terminates at operation 412. It may be noted that the flowchart 400 is explained to have above stated process operations; however, those skilled in the art would appreciate that the flowchart 400 may have more/less number of process operations which may enable all the above stated examples of the present disclosure.

It is to be appreciated that the Detailed Description section, and not any other section, is intended to be used to interpret the claims. Other sections can set forth one or more but not all examples as contemplated by the inventor(s), and thus, are not intended to limit this disclosure or the appended claims in any way.

Various examples have been disclosed herein, in connection with the above description and the drawings. It will be understood that it would be unduly repetitious to literally describe and illustrate all combinations and subcombinations of these examples. Accordingly, all examples can be combined in any way or combination. It will be appreciated by persons skilled in the art that the examples described herein are not limited to what has been particularly shown and described herein above. Particularly, it will be apparent to persons skilled in the art how to make and use aspects of this disclosure using data processing devices, computer systems, and computer architecture other than that described herein. A variety of modifications and variations are possible in light of the above teachings.

Examples have been described herein with the aid of functional building blocks illustrating the implementation of specified functions and relationships thereof. The boundaries of these functional building blocks have been arbitrarily defined herein for the convenience of the description. Alternate boundaries can be defined as long as the specified functions and relationships (or equivalents thereof) are appropriately performed. Also, alternative examples can perform functional blocks, steps, operations, and methods using orderings different than those described herein.

References herein to “one,” “one or more,” “an example,” or similar phrases, indicate that the example described can include a particular feature, structure, or characteristic. Moreover, such phrases are not necessarily referring to the same aspect. References herein that refer to a single feature, structure, or characteristic are not limited to examples with only a single feature, structure, or characteristic, and can be understood as referring to multiple features, structures, or characteristics as within the knowledge of persons skilled in the relevant art(s). For example, references to an “address” herein can be understood to refer to one address, more than one address, or a group of addresses. Additionally, some aspects can be described using the expression “coupled” and “connected,” along with their derivatives. Those terms are not necessarily intended as synonyms for each other. For example, some aspects can be described using the terms “connected” or “coupled” to indicate two or more elements are in direct physical or electrical contact with each other. The term “coupled,” however, can also mean that two or more elements are not in direct contact with each other, but yet still co-operate or interact with each other.

What is claimed is:

1. A system for swapping faulty memory addresses in a microcontroller, the system comprising:
a fault detection circuitry to detect a faulty memory address in a first memory;
a blacklist register to store the faulty memory address detected by the fault detection circuitry;
a comparator to compare a target memory address for a requested operation with the faulty memory address stored in the blacklist register; and
a control circuitry to, in response to a match between the target memory address and the faulty memory address stored in the blacklist register, direct the requested operation to a functional memory address in a second memory.

2. The system of claim 1, further comprising a memory controller to access the first memory and the second memory.

3. The system of claim 1, wherein the fault detection circuitry comprises a software diagnostic to detect the faulty memory address in the first memory.

4. The system of claim 1, wherein the fault detection circuitry comprises an error correcting code (ECC) circuitry.

5. The system of claim 1, wherein the blacklist register is volatile, and the faulty memory address is cleared in response to a reset of the microcontroller.

6. The system of claim 1, wherein the blacklist register is non-volatile, and the faulty memory address is persistently stored.

7. The system of claim 1, wherein the first memory comprises one of a volatile memory and a non-volatile memory.

8. The system of claim 1, wherein the second memory comprises a pre-defined set of memory addresses reserved for when the requested operation is directed to the second memory.

9. The system of claim 1, wherein the control circuitry activates a bus stall signal in response to the match between the target memory address and the faulty memory address.

10. The system of claim 1, wherein the comparator outputs a signal to a multiplexer to cause the multiplexer to output data received from one of the first memory and the second memory.

11. A method for swapping faulty memory addresses in a microcontroller, the method comprising:
detecting a faulty memory address in a first memory;
storing the faulty memory address in a register;
comparing a target memory address for a requested operation with the faulty memory address in the register; and
in response to a match between the target memory address and the faulty memory address in the register, directing the requested operation to a functional memory address in a second memory.

12. The method of claim 11, wherein the detecting is performed by a fault detection circuitry using a software diagnostic.

13. The method of claim 11, wherein the detecting is performed by an error correcting code (ECC) circuitry.

14. The method of claim 11, wherein the storing is performed by a volatile blacklist register, and the faulty memory address is cleared in response to a reset of the microcontroller.

15. The method of claim 11, wherein the storing is performed by a non-volatile blacklist register, and the faulty memory address is persistently stored.

16. The method of claim 11, wherein the second memory comprises a pre-defined set of memory addresses reserved for when the requested operation is directed to the second memory.

17. The method of claim 11, further comprising activating a bus stall signal in response to the match between the target memory address and the faulty memory address.

18. A non-transitory computer-readable medium having instructions stored thereon that, when executed by at least one computing device, cause the at least one computing device to perform operations comprising:
receiving a first memory address associated with an operation;
retrieving a list of faulty memory addresses;
comparing the first memory address to the list of faulty memory addresses; and
in response to the first memory address matching to the list of faulty memory addresses, directing the operation to a second memory address.

19. The non-transitory computer-readable medium of claim 18, wherein the operations further comprise:
in response to the first memory address matching to the list of faulty memory addresses, activating a bus stall signal.

20. The non-transitory computer-readable medium of claim 18, wherein the operations further comprise:
outputting a signal to indicate a matching status and to cause a multiplexer to output data received from one of the first memory and the second memory.
